(19) United States
(12) Patent Application Publication
(10) Pub. No.: US 2025/0219619 A1
(43) Pub. Date: Jul. 3, 2025

(54) DIGITAL SIGNAL PROCESSING SYSTEM FOR ACHIEVING IMPROVED FILTER BANK COMPUTATION PERFORMANCE WITH THE AID OF DATA ARRANGEMENT IN MEMORY

(71) Applicant: MEDIATEK INC., Hsinchu City (TW)

(72) Inventors: Xin-Wei Shih, Hsinchu City (TW); Tsung-Han Lee, Hsinchu City (TW)

(73) Assignee: MEDIATEK INC., Hsinchu City (TW)

(21) Appl. No.: 19/002,722

(22) Filed: Dec. 27, 2024

Related U.S. Application Data
(60) Provisional application No. 63/615,257, filed on Dec. 27, 2023.

(51) Int. Cl. H03H 17/06; H03H 17/02

(52) U.S. Cl. CPC H03H 17/06; H03H 17/0267

(57) ABSTRACT

A digital signal processing system includes a memory and a filter bank. The memory stores a plurality of data samples. The filter bank processes the plurality of data samples stored in the memory, and includes a plurality of filters, wherein the plurality of filters include a first group of filters that is arranged to process a first group of data samples included in the plurality of data samples stored in the memory, the first group of data samples includes data samples loaded and processed by taps of each filter included in the first group of filters that are stored in discontinuous memory positions of the memory.

### CROSS REFERENCE TO RELATED APPLICATIONS

This application claims the benefit of U.S. Provisional Application No. 63/615,257, filed on Dec. 27, 2023. The content of the application is incorporated herein by reference.

### BACKGROUND

The present invention relates to digital signal processing, and more particularly, to a digital signal processing system for achieving improved filter bank computation performance with the aid of data arrangement in a memory.

A processing circuit may load a value from a memory, perform an arithmetic operation upon the value, and store a processed value into the memory. A good data structure used in the memory can provide fast data operations, including store, access, update, etc., and can improve the computation efficiency of the processing circuit. In addition, the computation efficiency of the processing circuit can be further improved if utilization of registers used by the processing circuit can be maximized. Thus, there is need for an innovative data structure in a memory that is capable maximizing the utilization of registers for achieving computation efficiency improvement of the processing circuit.

### SUMMARY

One of the objectives of the claimed invention is to provide a digital signal processing system for achieving improved filter bank computation performance with the aid of data arrangement in a memory.

According to a first aspect of the present invention, an exemplary digital signal processing system is disclosed. The exemplary digital signal processing system includes a memory and a filter bank. The memory is arranged to store a plurality of data samples. The filter bank is arranged to process the plurality of data samples stored in the memory, and includes a plurality of filters, wherein the plurality of filters include a first group of filters that is arranged to process a first group of data samples included in the plurality of data samples stored in the memory, the first group of data samples includes data samples loaded and processed by taps of each filter included in the first group of filters that are stored in discontinuous memory positions of the memory.

According to a second aspect of the present invention, an exemplary data arrangement method is disclosed. The exemplary data arrangement method is applied to a memory that is accessible to a filter bank. The exemplary data arrangement method includes: storing filter data of the filter bank into the memory, wherein the filter data includes a plurality of data samples, the plurality of data samples include a first group of data samples for a first group of filters included in the filter bank, the first group of data samples includes data samples loaded and processed by taps of each filter included in the first group of filters that are stored in discontinuous memory positions of the memory.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a digital signal processing system according to an embodiment of the present invention.

FIG. 2 is a diagram illustrating a filter bank having eight 8-tap filters used for filtering of eight frequency bands according to an embodiment of the present invention.

FIG. 3 is a diagram illustrating a data arrangement design having transposed filter data stored in a memory according to an embodiment of the present invention.

FIG. 4 is a diagram illustrating a generalized data structure employed by the proposed data arrangement design according to an embodiment of the present invention.

FIG. 5 is a diagram illustrating a data arrangement design using non-folding groups and folding groups according to an embodiment of the present invention.

FIGS. 6-8 are diagrams illustrating a circular update scheme applied to a non-folding group that has data samples loaded and processed by eight 8-tap filters in a filter bank according to an embodiment of the present invention.

FIGS. 9-11 are diagrams illustrating a circular update scheme applied to a folding-2 group that has data samples loaded and processed by four 8-tap filters in a filter bank according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

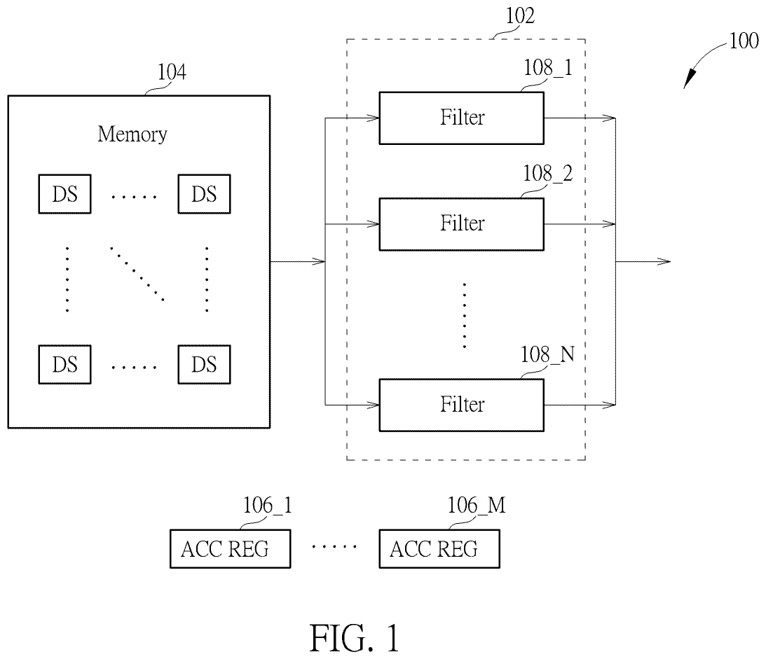

FIG. 1 is a diagram illustrating a digital signal processing system according to an embodiment of the present invention. The digital signal processing system 100 includes a filter bank 102, a memory 104, and a plurality of accumulation (ACC) registers (labeled by “ACC REG” 106_1-106_M (M≥2). The filter bank 102 includes a plurality of filters 108_1-108_N (N≥2). The memory 104 is arranged to store a plurality of data samples DS to be processed by the filters 108_1-108_N of the filter bank 102. The filter bank 102 is arranged to process the data samples DS stored in the memory 104. For example, each of the data samples DS may be audio data, audio sample or any other type of data and/or samples related to audio, and the filters 108_1-108_N are used to process audio data/samples of N frequency bands, respectively. The filters 108_1-108_N may have the same filter length (i.e., the same tap number).

Consider a case where the filter bank 102 has three 4-tap filters 108_1, 108_2, 108_N (N=3) for dealing with filtering of three frequency bands {Band 0, Band 1, Band 3}. A filter coefficient at tap i for frequency band b is denoted by c_{b,i}. A data sample at time t for frequency band b is denoted by d_{b,t}. Regarding filtering at time t, data samples {d_{0,t}, d_{0,t-1}-d_{0,t-2}-d_{0,t-3}} are read from the memory 104, and then multiplied with filter coefficients {c_{0,0}, c_{0,1}, c_{0,2}, c_{0,3}} of the filter 108_1; the data samples {d_{1,t}, d_{1,t-1}, d_{1,t-2}, d_{1,t-3}} are read from the memory 104, and then multiplied with filter coefficients {c_{1,0}, c_{1,1}, c_{1,2}, c_{1,3}} of the filter 108_2; and the data samples {d_{2,t}, d_{2,t-1}, d_{2,t-2}, d_{2,t-3}} are read from the memory 104, and then multiplied with filter coefficients {c_{2,0}, c_{2,1}, c_{2,2}, c_{2,3}} of the filter 108_N (N=3). The filtering at time t may be expressed using the following equations.

$$Band 0 : \{ {c}_{0 , 0} , {c}_{0 , 1} , {c}_{0 , 2} , {c}_{0 , 3} \} \times \{ {d}_{0 , t} , {d}_{0 , t - 1} , {d}_{0 , t - 2} , {d}_{0 , t - 3} \} \qquad ( 1 )$$

$$Band 1 : \{ {c}_{1 , 0} , {c}_{1 , 1} , {c}_{1 , 2} , {c}_{1 , 3} \} \times \{ {d}_{1 , t} , {d}_{1 , t - 1} , {d}_{1 , t - 2} , {d}_{1 , t - 3} \} \qquad ( 2 )$$

$$Band 2 : \{ {c}_{2 , 0} , {c}_{2 , 1} , {c}_{2 , 2} , {c}_{2 , 3} \} \times \{ {d}_{2 , t} , {d}_{2 , t - 1} , {d}_{2 , t - 2} , {d}_{2 , t - 3} \} \qquad ( 3 )$$

Due to audio streaming, there are new data samples d_{0,t+1}, d_{1,t+1}, d_{2,t+1} coming at time t+1. The data samples {d_{0,t}, d_{0,t-1}, d_{0,t-2}, d_{0,t-3}} in the memory 104 are updated by {d_{0,t+1}, d_{0,t}, d_{0,t-1}, d_{0,t-2}} due to insertion of the latest data sample d_{0,t+1}. The data samples {d_{1,t}, d_{1,t-1}, d_{1,t-2}, d_{1,t-3}} in the memory 104 are updated by {d_{1,t+1}, d_{1,t}, d_{1,t-1}, d_{1,t-2}} due to insertion of the latest data sample d_{1,t+1}. The data samples {d_{2,t}, d_{2,t-1}, d_{2,t-2}, d_{2,t-3}} in the memory 104 are updated by {d_{2,t+1}, d_{2,t}, d_{2,t-1}, d_{2,t-2}} due to the latest data sample d_{2,t+1}. Regarding filtering at time t+1, data samples {d_{0,t+1}, d_{0,t}, d_{0,t-1}, d_{0,t-2}} are read from the memory 104, and then multiplied with filter coefficients {c_{0,0}, c_{0,1}, c_{0,2}, c_{0,3}} of the filter 108_1; the data samples {d_{1,t+1}, d_{1,t}, d_{1,t-1}, d_{1,t-2}} are read from the memory 104, and then multiplied with filter coefficients {c_{1,0}, c_{1,1}, c_{1,2}, c_{1,3}} of the filter 108_2; and the data samples {d_{2,t+1}, d_{2,t}, d_{2,t-1}, d_{2,t-2}} are read from the memory 104, and then multiplied with filter coefficients {c_{2,0}, c_{2,1}, c_{2,2}, c_{2,3}} of the filter 108_N (N=3). The filtering at time t+1 may be expressed using the following equations.

$$Band 0 : \{ {c}_{0 , 0} , {c}_{0 , 1} , {c}_{0 , 2} , {c}_{0 , 3} \} \times \{ {d}_{0 , t + 1} , {d}_{0 , t} , {d}_{0 , t - 1} , {d}_{0 , t - 2} \} \qquad ( 4 )$$

$$Band 1 : \{ {c}_{1 , 0} , {c}_{1 , 1} , {c}_{1 , 2} , {c}_{1 , 3} \} \times \{ {d}_{1 , t + 1} , {d}_{1 , t} , {d}_{1 , t - 1} , {d}_{1 , t - 2} \} \qquad ( 5 )$$

$$Band 2 : \{ {c}_{2 , 0} , {c}_{2 , 1} , {c}_{2 , 2} , {c}_{2 , 3} \} \times \{ {d}_{2 , t + 1} , {d}_{2 , t} , {d}_{2 , t - 1} , {d}_{2 , t - 2} \} \qquad ( 6 )$$

Each of the ACC registers 106_1-106_M can be used to store a value of a multiply-and-accumulation (MAC) operation. If the utilization of the ACC registers 106_1-106_M can be maximized, the computation performance of the filter bank 102 can be improved. In this embodiment, the number of the ACC registers 106_1-106_M is smaller than the number of filters 108_1-108_N implemented in the filter bank 102 (i.e., M<N). To achieve the objective of maximizing utilization of the ACC registers 106_1-106_M, the present invention proposes an innovative data arrangement design which specifies a data structure of the filter data (i.e., data samples DS) stored in the memory 104. Further details of the proposed data arrangement design are described as below with reference to the accompanying drawings.

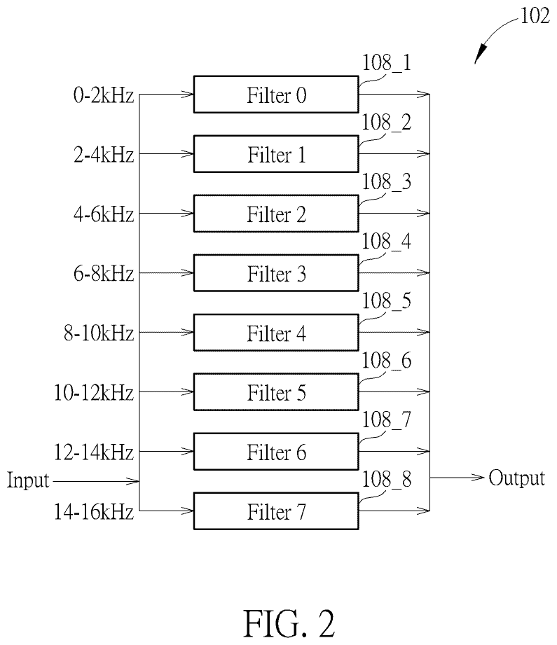

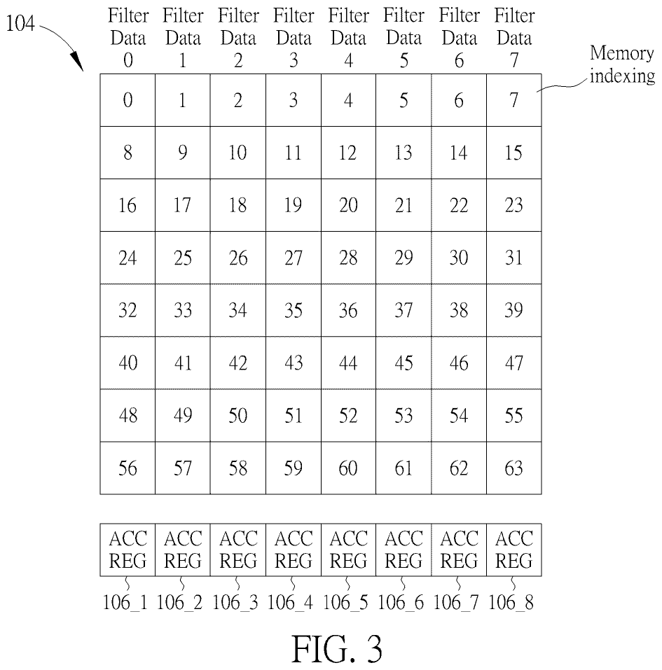

FIG. 2 is a diagram illustrating a filter bank having eight 8-tap filters used for filtering of eight frequency bands according to an embodiment of the present invention. FIG. 3 is a diagram illustrating a data arrangement design having transposed filter data stored in a memory according to an embodiment of the present invention. The filter bank 102 has eight filters (labeled by “filter 0”, “filter 1”, “filter 2”, “filter 3”, “filter 4”, “filter 5”, “filter 6”, “filter 7”) 108_1-108_8. At time t, the filter 108_1 with eight tap coefficients {c_{0,0}, c_{0,1}, c_{0,2}, c_{0,3}, c_{0,4}, c_{0,5}, c_{0,6}, c_{0,7}} is arranged to process filter data 0 with eight data samples {d_{0,t}, d_{0,t-1}, d_{0,t-2}, d_{0,t-3}, d_{0,t-4}, d_{0,t-5}, d_{0,t-6}, d_{0,t-7}}, the filter 108_2 with eight tap coefficients {c_{1,0}, c_{1,1}, c_{1,2}, c_{1,3}, c_{1,4}, c_{1,5}, c_{1,6}, c_{1,7}} is arranged to process filter data 1 with eight data samples {d_{1,t}, d_{1,t-1}, d_{1,t-2}, d_{1,t-3}, d_{1,t-4}, d_{1,t-5}, d_{1,t-6}, d_{1,t-7}}, the filter 108_3 with eight tap coefficients {c_{2,0}, c_{2,1}, c_{2,2}, c_{2,3}, c_{2,4}, c_{2,5}, c_{2,6}, c_{2,7}} is arranged to process filter data 2 with eight data samples {d_{2,t}, d_{2,t-1}, d_{2,t-2}, d_{2,t-3}, d_{2,t-4}, d_{2,t-5}, d_{2,t-6}, d_{2,t+7}}, the filter 108_4 with eight tap coefficients {c_{3,0}, c_{3,1}, c_{3,2}, c_{3,3}, c_{3,4}, c_{3,5}, c_{3,6}, c_{3,7}} is arranged to process filter data 3 with eight data samples {d_{3,t}, d_{3,t-1}, d_{3,t-2}, d_{3,t-3}, d_{3,t-4}, d_{3,t-5}, d_{3,t-6}, d_{3,t-7}}, the filter 108_5 with eight tap coefficients {c_{4,0}, c_{4,1}, c_{4,2}, c_{4,3}, c_{4,4}, c_{4,5}, c_{4,6}, c_{4,7}} is arranged to process filter data 4 with eight data samples {d_{4,t}, d_{4,t-1}, d_{4,t-2}, d_{4,t-3}, d_{4,t-4}, d_{4,t-5}, d_{4,t-6}, d_{4,t-7}}, the filter 108_6 with eight tap coefficients {c_{5,0}, c_{5,1}, c_{5,2}, c_{5,3}, c_{5,4}, c_{5,5}, c_{5,6}, c_{5,7}} is arranged to process filter data 5 with eight data samples {d_{5,t}, d_{5,t-1}, d_{5,t-2}, d_{5,t-3}, d_{5,t-4}, d_{5,t-5}, d_{5,t-6}, d_{5,t-7}}, the filter 108_7 with eight tap coefficients {c_{6,0}, c_{6,1}, c_{6,2}, c_{6,3}, c_{6,4}, c_{6,5}, c_{6,6}, c_{6,7}} is arranged to process filter data 6 with eight data samples {d_{6,t}, d_{6,t-1}, d_{6,t-2}, d_{6,t-3}, d_{6,t-4}, d_{6,t-5}, d_{6,t-6}, d_{6,t-7}}, and the filter 108_8 with eight tap coefficients {c_{7,0}, c_{7,1}, c_{7,2}, c_{7,3}, c_{7,4}, c_{7,5}, c_{7,6}, c_{7,7}} is arranged to process filter data 7 with eight data samples {d_{7,t}, d_{7,t-1}, d_{7,t-2}, d_{7,t-3}, d_{7,t-4}, d_{7,t-5}, d_{7,t-6}, d_{7,t-7}}.

The memory 104 has a plurality of memory positions indexed by {0, 1, 2, . . . , 61, 62, 63}. In this embodiment, the memory positions indexed by {0, 1, 2, 3, 4, 5, 6, 7} are continuous memory positions, the memory positions indexed by {8, 9, 10, 11, 12, 13, 14, 15} are continuous memory positions, the memory positions indexed by {16, 17, 18, 19, 20, 21, 22, 23} are continuous memory positions, the memory positions indexed by {24, 25, 26, 27, 28, 29, 30, 31} are continuous memory positions, the memory positions indexed by {32, 33, 34, 35, 36, 37, 38, 39} are continuous memory positions, the memory positions indexed by {40, 41, 42, 43, 44, 45, 46, 47} are continuous memory positions, the memory positions indexed by {48, 49, 50, 51, 52, 53, 54, 55} are continuous memory positions, and the memory positions indexed by {56, 57, 58, 59, 60, 61, 62, 63} are continuous memory positions. In addition, the memory positions indexed by {0, 8, 16, 24, 32, 40, 48, 56} are discontinuous memory positions, the memory positions indexed by {1, 9, 17, 25, 33, 41, 49, 57} are discontinuous memory positions, the memory positions indexed by {2, 10, 18, 26, 34, 42, 50, 58} are discontinuous memory positions, the memory positions indexed by {3, 11, 19, 27, 35, 43, 51, 59} are discontinuous memory positions, the memory positions indexed by {4, 12, 20, 28, 36, 44, 52, 60} are discontinuous memory positions, the memory positions indexed by {5, 13, 21, 29, 37, 45, 53, 61} are discontinuous memory positions, the memory positions indexed by {6, 14, 22, 30, 37, 46, 54, 62} are discontinuous memory positions, and the memory positions indexed by {7, 15, 23, 31, 39, 47, 55, 63} are discontinuous memory positions.

In accordance with the proposed data arrangement design, the filter data 0-7 are transposed and stored in the memory 104. Specifically, the filter data 0 has data samples {d_{0,t}, d_{0,t-1}, d_{0,t-2}, d_{0,t-3}, d_{0,t-4}, d_{0,t-5} d_{0,t-6}, d_{0,t-7}} stored in discontinuous memory positions indexed by {0, 8, 16, 24, 32, 40, 48, 56}, respectively; the filter data 1 has data samples {d_{1,t}, d_{1,t-1}, d_{1,t-2}, d_{1,t-3}, d_{1,t-4}, d_{1,t-5}, d_{1,t-6}, d_{1,t-7}} stored in discontinuous memory positions indexed by {1, 9, 17, 25, 33, 41, 49, 57}, respectively; the filter data 2 has data samples {d_{2,t}, d_{2,t-1}, d_{2,t-2}, d_{2,t-3}, d_{2,t-4}, d_{2,t-5}, d_{2,t-6}, d_{2,t-7}} stored in discontinuous memory positions indexed by {2, 10, 18, 26, 34, 42, 50, 58}, respectively; the filter data 3 has data samples {d_{3,t}, d_{3,t-1}, d_{3,t-2}, d_{3,t-3}, d_{3,t-4}, d_{3,t-5}, d_{3,t-6}, d_{3,t-7}} stored in discontinuous memory positions indexed by {3, 11, 19, 27, 35, 43, 51, 59}, respectively; the filter data 4 has data samples {d_{4,t}, d_{4,t-1}, d_{4,t-2}, d_{4,t-3}, d_{4,t-4}, d_{4,t-5}, d_{4,t-6}, d_{4,t-7}} stored in discontinuous memory positions indexed by {4, 12, 20, 28, 36, 44, 52, 60}, respectively; the filter data 5 has data samples {d_{5,t}, d_{5,t-1}, d_{5,t-2}, d_{5,t-3}, d_{5,t-4}, d_{5,t-5}, d_{5,t-6}, d_{5,t-7}} stored in discontinuous memory positions indexed by {5, 13, 21, 29, 37, 45, 53, 61}, respectively; the filter data 6 has data samples {d_{6,t}, d_{6,t-1}, d_{6,t-2}, d_{6,t-3}, d_{6,t-4}, d_{6,t-5}, d_{6,t-6}, d_{6,t-7}} stored in discontinuous memory positions indexed by {6, 14, 22, 30, 37, 46, 54, 62}, respectively; and the filter data 7 has data samples {d_{7,t}, d_{7,t-1}, d_{7,t-2}, d_{7,t-3}, d_{7,t-4}, d_{7,t-5}, d_{7,t-6}, d_{7,t-7}} stored in discontinuous memory positions indexed by {7, 15, 23, 31, 39, 47, 55, 63}, respectively.

In this embodiment, the memory index order is the same as the instruction order. Hence, the filter bank 102 iterates and computes taps one by one for each filter. In other words, the filter 108_1 computes c_{0,0}×d_{0,t}, the filter 108_2 computes c_{1,0}×d_{1,t}, the filter 108_3 computes c_{2,0}×d_{2,t}, the filter 108_4 computes c_{3,0}×d_{3,t}, the filter 108_5 computes c_{4,0}×d_{4,t}, the filter 108_6 computes c_{5,0}×d_{5,t}, the filter 108_7 computes c_{6,0}×d_{6,t}, and the filter 108_8 computes c_{7,0}×d_{7,t}, where the ACC register 106_1 is active to store a computation result of c_{0,0}×d_{0,t}, the ACC register 106_2 is active to store a computation result of c_{1,0}×d_{1,t}, the ACC register 103_3 is active to store a computation result of c_{2,0}×d_{2,t}, the ACC register 106_4 is active to store a computation of c_{3,0}×d_{3,t}, the ACC register 106_5 is active to store a computation of c_{4,0}×d_{4,t}, the ACC register 106_6 is active to store a computation of c_{5,0}×d_{5,t}, the ACC register 106_7 is active to store a computation of c_{6,0}×d_{6,t}, and the ACC register 106_8 is active to store a computation of c_{7,0}×d_{7,t}.

After computations of first taps {c_{0,0}, c_{1,0}, c_{2,0}, c_{3,0}, c_{4,0}, c_{5,0}, c_{6,0}, c_{7,0}} of all filters 108_1-108_8 are completed, computations of second taps {c_{0,1}, c_{1,1}, c_{2,1}, c_{3,1}, c_{4,1}, c_{5,1}, c_{6,1}, c_{7,1}} of all filters 108_1-108_8 are started. Hence, the filter 108_1 computes c_{0,1}×d_{0,t-1}, the filter 108_2 computes c_{1,1}×d_{1,t-1}, the filter 108_3 computes c_{2,1}×d_{2,t-1}, the filter 108_4 computes c_{3,1}×d_{3,t-1}, the filter 108_5 computes c_{4,1}×d_{4,t-1}, the filter 108_6 computes c_{5,1}×d_{5,t-1}, the filter 108_7 computes c_{6,1}×d_{6,t-1}, and the filter 108_8 computes c_{7,1}×d_{7,t-1}, where the ACC register 106_1 is active to store a computation result of c_{0,0}×d_{0,t}+c_{0,1}×d_{0,t-1}, the ACC register 106_2 is active to store a computation result of c_{1,0}×d_{1,t}+c_{1,1}×d_{1,t-1}, the ACC register 103_3 is active to store a computation result of c_{2,0}×d_{2,t}+c_{2,1}×d_{2,t-1}, the ACC register 106_4 is active to store a computation of c_{3,0}×d_{3,t}+c_{3,1}×d_{3,t-1}, the ACC register 106_5 is active to store a computation of c_{4,0}×d_{4,t}+c_{4,1}×d_{4,t-1}, the ACC register 106_6 is active to store a computation of c_{5,0}×d_{5,t}+c_{5,1}×d_{5,t-1}, the ACC register 106_7 is active to store a computation of c_{6,0}×d_{6,t}+c_{6,1}×d_{6,t-1}, and the ACC register 106_8 is active to store a computation of c_{7,0}×d_{7,t}+c_{7,1}×d_{7,t-1}.

Similarly, after computations of second taps {c_{0,1}, c_{1,1}, c_{2,1}, c_{3,1}, c_{4,1}, c_{5,1}, c_{6,1}, c_{7,1}} of all filters 108_1-108_8 are completed, computations of third taps {c_{0,2}, c_{1,2}, c_{2,2}, c_{3,2}, c_{4,2}, c_{5,2}, c_{6,2}, c_{7,2}} of all filters 108_1-108_8 are started; after computations of third taps {c_{0,2}, c_{1,2}, c_{2,2}, c_{3,2}, c_{4,2}, c_{5,2}, c_{6,2}, c_{7,2}} of all filters 108_1-108_8 are completed, computations of fourth taps {c_{0,3}, c_{1,3}, c_{2,3}, c_{3,3}, c_{4,3}, c_{5,3}, c_{6,3}, c_{7,3}} of all filters 108_1-108_8 are started; after computations of fourth taps {c_{0,3}, c_{1,3}, c_{2,3}, c_{3,3}, c_{4,3}, c_{5,3}, c_{6,3}, c_{7,3}} of all filters 108_1-108_8 are completed, computations of fifth taps {c_{0,4}, c_{1,4}, c_{2,4}, c_{3,4}, c_{4,4}, c_{5,4}, c_{6,4}, c_{7,4}} of all filters 108_1-108_8 are started; after computations of fifth taps {c_{0,4}, c_{1,4}, c_{2,4}, c_{3,4}, c_{4,4}, c_{5,4}, c_{6,4}, c_{7,4}} of all filters 108_1-108_8 are completed, computations of sixth taps {c_{0,5}, c_{1,5}, c_{2,5}, c_{3,5}, c_{4,5}, c_{5,5}, c_{6,5}, c_{7,5}} of all filters 108_1-108_8 are started; after computations of sixth taps {c_{0,5}, c_{1,5}, c_{2,5}, c_{3,5}, c_{4,5}, c_{5,5}, c_{6,5}, c_{7,5}} of all filters 108_1-108_8 are completed, computations of seventh taps {c_{0,6}, c_{1,6}, c_{2,6}, c_{3,6}, c_{4,6}, c_{5,6}, c_{6,6}, c_{7,6}} of all filters 108_1-108_8 are started; and after computations of seventh taps {c_{0,6}, c_{1,6}, c_{2,6}, c_{3,6}, c_{4,6}, c_{5,6}, c_{6,6}, c_{7,6}} of all filters 108_1-108_8 are completed, computations of eighth taps {c_{0,7}, c_{1,7}, c_{2,7}, c_{3,7}, c_{4,7}, c_{5,7}, c_{6,7}, c_{7,7}} of all filters 108_1-108_8 are started.

A related data arrangement design may have filter data 0 stored in continuous memory positions indexed by {0, 1, 2, 3, 4, 5, 6, 7}, filter data 1 stored in continuous memory positions indexed by {8, 9, 10, 11, 12, 13, 14, 15}, filter data 2 stored in continuous memory positions {16, 17, 18, 19, 20, 21, 22, 23}, filter data 3 stored in continuous memory positions indexed by {24, 25, 26, 27, 28, 29, 30, 31}, filter data 4 stored in continuous memory positions indexed by {32, 33, 34, 35, 36, 37, 38, 39}, filter data 5 stored in continuous memory positions indexed by {40, 41, 42, 43, 44, 45, 46, 47}, filter data 6 stored in continuous memory positions indexed by {48, 49, 50, 51, 52, 53, 54, 55}, and filter data 7 stored in continuous memory positions indexed by {56, 57, 58, 59, 60, 61, 62, 63}. Hence, the filter bank 102 performs computations of taps of one filter after computations of all taps of another filter are completed, and only one ACC register is used during computations of taps of the same filter. Compared to the related data arrangement design, the proposed data arrangement design with transposed filter data stored in a memory enables multiple ACC registers to be used during computations of i^{th} taps (i={1, . . . , 856}) of all filters 108_1-108_8. In this way, the filter bank computation performance can be improved due to increased utilization of ACC registers.

In practice, the number of filters 108_1-108_N included in the filter bank 102 may be larger than the number of ACC registers 106_1-106_M (i.e., N≥M). To maximize the utilization of the ACC registers 106_1-106_M, the filters 108_1-108_N may be divided into a plurality of groups of filters, and the proposed data arrangement design may divide data samples DS to be processed by the filters 108_1-108_N into a plurality of groups of data samples that correspond to the plurality of groups of filters, respectively, where the plurality of groups of data samples may include non-folding group(s), folding group(s), or a combination thereof, depending upon actual design considerations.

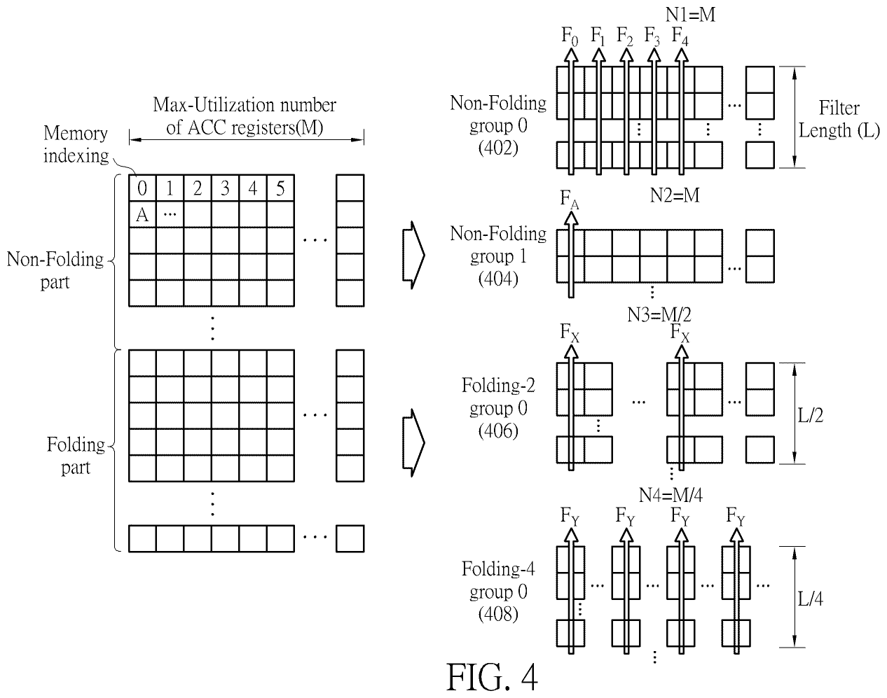

FIG. 4 is a diagram illustrating a generalized data structure employed by the proposed data arrangement design according to an embodiment of the present invention. The filters 108_1-108_N may have the same filter length (i.e., the same tap number) L. The filters 108_1-108_N may include a first group of filters that is arranged to process a first group of data samples (which is a non-folding group 402) stored in the memory 104, where the number N1 of filters included in the first group of filters is equal to the number of ACC registers 108_1-108_M (i.e., N1=M), the non-folding group 402 includes 1 data sample loaded and processed by L times of each filter included in the first group of filters that are stored in discontinuous memory positions of the memory 104, and include M data samples loaded and processed at memory position index i (i={1, . . . , M}) for M different filters included in the first group of filters that are stored in continuous memory positions of the memory 104.

In some embodiments of the present invention, data samples stored in the memory 104 may include more than one non-folding group. The filters 108_1-108_N may further include a second group of filters that is arranged to process a second group of data samples (which is a non-folding group 404) stored in the memory 104, where the number N2 of filters included in the second group of filters is equal to the number of ACC registers 108_1-108_M (i.e., N2=M), the non-folding group 404 includes 1 data sample loaded and processed by L times of each filter included in the second group of filters that are stored in discontinuous memory positions of the memory 104, and include M data samples loaded and processed at memory position index i (i={1, . . . , M}) for M different filters included in the second group of filters that are stored in continuous memory positions of the memory 104.

In some embodiments of the present invention, the filters 108_1-108_N may include a third group of filters that is arranged to process a third group of data samples (which is a folding-2 group 406 with a folding size of 2) stored in the memory 104, where the number N3 of filters included in the third group of filters is smaller than the number of ACC registers 108_1-108_M

$$( i . e . , N 3 = \frac{M}{2} ) ,$$

the folding-2 group 406 includes 2

$$( i . e . , \frac{M}{N 3} = 2 )$$

data samples (or called taps) loaded and processed by

$$\frac{L}{2}$$

times of each filter included in the third group of filters that are stored in discontinuous memory positions of the memory 104, and include M data samples loaded and processed at memory position index i and

$$( i + \frac{M}{2} ) ( i = \{ 1 , … , \frac{M}{2} \} ) for \frac{M}{2}$$

different filters included in the third group of filters that are stored in continuous memory positions of the memory 104. It should be noted that, regarding each filter included in the third group of filters, partial accumulation results are stored in 2 ACC registers, and a final accumulation result is obtained by perform post-ACC summation(s) upon partial accumulation results stored in 2 ACC registers.

In some embodiments of the present invention, data samples stored in the memory 104 may include more than one folding group. The filters 108_1-108_N may include a fourth group of filters that is arranged to process a fourth group of data samples (which is a folding-4 group 408 with a folding size of 4) stored in the memory 104, where the number N4 of filters included in the fourth group of filters is different from the number N3 of filters included in the third group of filters (i.e., N4≠N3) and is smaller than the number of ACC registers 108_1-108_M

$$( i . e . , N 4 = \frac{M}{4} ) ,$$

the folding-4 group 408 includes 4

$$( i . e . , \frac{M}{N 4} = 4 )$$

data samples (or called taps) loaded and processed by

$$\frac{L}{4}$$

times of each filter included in the fourth group of filters that are stored in discontinuous memory positions of the memory 104, and include M data samples loaded and processed at memory position index i,

$$( i + \frac{M}{4} ) , \qquad ( i + \frac{M}{2} ) and ( i + \frac{3 M}{4} ) \qquad ( i = \{ 1 , … , \frac{M}{4} \} ) for \frac{M}{4}$$

different filters included in the fourth group of filters that are stored in continuous memory positions of the memory 104. It should be noted that, regarding each filter included in the third group of filters, partial accumulation results are stored in 4 ACC registers, and a final accumulation result is obtained by perform post-ACC summation(s) upon partial accumulation results stored in 4 ACC registers. The folding-4 group 408 requires more post-ACC summations compared to the folding-2 group 406.

In some embodiments of the present invention, a non-folding group has high priority than a folding group, and a folding group with a smaller folding size has higher priority than a folding group with a larger folding size. If the number of filters 108_1-108_N is divisible by the number of ACC registers 106_1-106_M, the proposed data arrangement design preferably uses non-folding groups only to avoid memory copy needed to update data and any post-ACC summation. If the number of filters 108_1-108_N is not divisible by the number of ACC registers 106_1-106_M, the proposed data arrangement design first uses non-folding groups to avoid memory copy needed to update data and any post-ACC summation, and then preferably uses folding groups with smaller folding size (e.g., folding-2 groups) that require less memory copy needed to update data and less post-ACC summation.

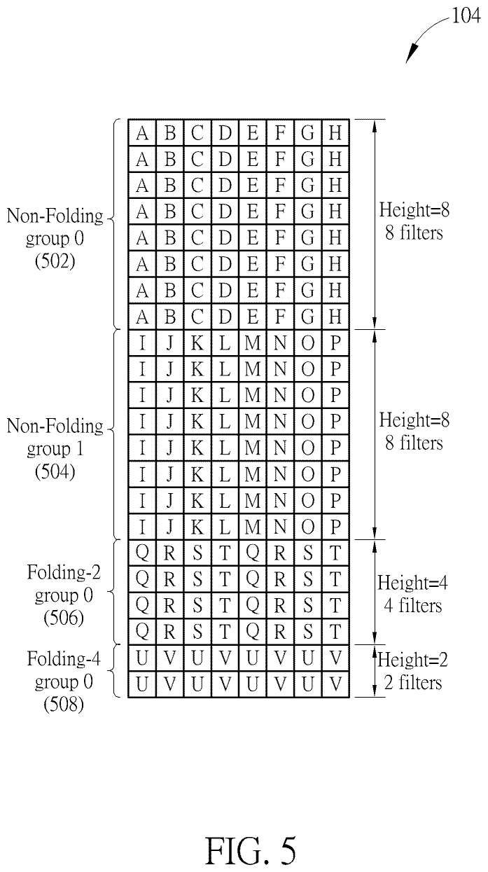

FIG. 5 is a diagram illustrating a data arrangement design using non-folding groups and folding groups according to an embodiment of the present invention. In this embodiment, the number of filters 108_1-108_N included in the filter bank 102 is equal to 22 (i.e., N=22), the filter length of each of the filters 108_1-108_N is equal to 8 (i.e., L=8), the number of ACC registers 106_1-106_M is equal to 8 (i.e., M=8), and the N×L data samples stored in the memory 104 is divided into two non-folding groups 502, 504, one folding-2 group 506, and one folding-4 group 508, where the non-folding group 502 includes data samples (labeled by “A”, “B”, “C”, “D”, “E”, “F”, “G”, and “H”, each belonging to filter data of a same filter and stored in discontinuous memory positions) to be loaded and processed by 8 filters (e.g., 108_1-108_8) of the filter bank 102, the non-folding group 504 includes data samples (labeled by “I”, “I”, “K”, “L”, “M”, “N”, “O”, and “P”, each belonging to filter data of a same filter and stored in discontinuous memory positions due to data transposing) to be loaded and processed by 8 filters (e.g., 108_9-108_16) of the filter bank 102, the folding-2 group 506 includes data samples (labeled by “Q”, “R”, “S”, and “T”, each belonging to filter data of a same filter and stored in discontinuous memory positions due to data transposing) to be loaded and processed by 4 filters (e.g., 108_17-108_20) of the filter bank 102, and the folding-4 group 506 includes data samples (labeled by “U” and “V”, each belonging to filter data of a same filter and stored in discontinuous memory positions due to data transposing) to be loaded and processed by 2 filters (e.g., 108_21-108_N, where N=22) of the filter bank 102.

According to the data arrangement shown in FIG. 5, the group of 8 filters (e.g., 108_9-108_16) of the filter bank 102 is arranged to load and process data samples included in the non-folding group 504 after the group of 8 filters (e.g., 108_1-108_8) of the filter bank 102 finishes processing of data samples included in the non-folding group 502, the group of 4 filters (e.g., 108_17-108_20) of the filter bank 102 is arranged to load and process data samples included in the folding-2 group 506 after the group of 8 filters (e.g., 108_9-108_16) of the filter bank 102 finishes processing of data samples included in the non-folding group 504, and the group of 2 filters (e.g., 108_21-108_N, where N=22) of the filter bank 102 is arranged to load and process data samples included in the folding-4 group 508 after the group of 4 filters (e.g., 108_17-108_20) of the filter bank 102 finishes processing of data samples included in the folding-2 group 502.

As mentioned above, a non-folding group has high priority than a folding group, and a folding group with a smaller folding size has higher priority than a folding group with a larger folding size. Hence, the data arrangement design of data samples to be processed by the filter bank 102 may include non-folding groups only, or may include folding groups only, or may include non-folding group(s) and folding group(s), depending upon the number of filters 108_1-108_N included in the filter bank 102 and the number of ACC registers 106_1-106_M available to the filter bank 102. By way of example, but not limitation, several data arrangement designs are shown in the following table.

TABLE 1

| # | # | Size Groups | Size Groups | Size Groups | Size Groups |
|---|---|---|---|---|---|
| Filter | ACC | (Non-folding) | (Folding-2) | (Folding-4) | (Folding-8) |
| 22 | 8 | 8, 8 | 4 | 2 | 0 |
| 10 | 8 | 8 | 0 | 2 | 0 |
| 7 | 8 | 0 | 4 | 2 | 1 |

Regarding the data arrangement design shown in FIG. 2, the filter data 0-7 are transposed and stored in the memory 104 at time t. When new data samples (i.e., latest data samples) are coming at time t+1, the filter data 0-7 should be updated. The proposed data arrangement design may employ a circular update scheme to avoid inefficient data movement when updating the filter data. In accordance with the circular update scheme, when a latest data sample to be processed by a filter comes, the latest data sample is inserted into the memory in a circular way among a plurality of selected memory positions, and an earliest data sample that is stored in the memory and processed by the filter is overwritten by the latest data sample or a data sample shifted from a selected memory position before the latest data sample is stored into the selected memory position.

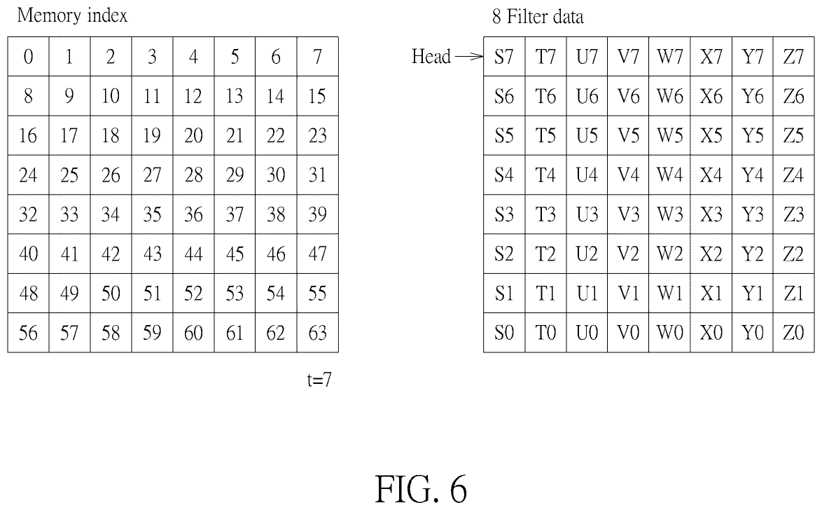

FIGS. 6-8 are diagrams illustrating a circular update scheme applied to a non-folding group that has data samples loaded and processed by eight 8-tap filters in a filter bank according to an embodiment of the present invention. The filter data of a first 8-tap filter S includes 8 data samples that are stored in discontinuous memory positions indexed by {0, 8, 16, 24, 32, 40, 48, 56}, respectively; the filter data of a second 8-tap filter T includes 8 data samples that are stored in stored in discontinuous memory positions indexed by {1, 9, 17, 25, 33, 41, 49, 57}, respectively; the filter data of a third 8-tap filter U includes 8 data samples stored in discontinuous memory positions indexed by {2, 10, 18, 26, 34, 42, 50, 58}, respectively; the filter data of a fourth 8-tap filter V includes 8 data samples stored in discontinuous memory positions indexed by {3, 11, 19, 27, 35, 43, 51, 59}, respectively; the filter data of a fifth 8-tap filter W includes 8 data samples stored in discontinuous memory positions indexed by {4, 12, 20, 28, 36, 44, 52, 60}, respectively; the filter data of a sixth 8-tap filter X includes 8 data samples stored in discontinuous memory positions indexed by {5, 13, 21, 29, 37, 45, 53, 61}, respectively; the filter data of a seventh 8-tap filter Y includes 8 data samples stored in discontinuous memory positions indexed by {6, 14, 22, 30, 37, 46, 54, 62}, respectively; and the filter data of an eighth 8-tap filter Z includes 8 data samples stored in discontinuous memory positions indexed by {7, 15, 23, 31, 39, 47, 55, 63}, respectively.

In accordance with the circular update scheme, a latest data sample of the first 8-tap filter S is inserted into the memory in a circular way among memory positions indexed by {0, 8, 16, 24, 32, 40, 48, 56}, a latest data sample of the second 8-tap filter T is inserted into the memory in a circular way among memory positions indexed by {1, 9, 17, 25, 33, 41, 49, 57}, a latest data sample of the third 8-tap filter U is inserted into the memory in a circular way among memory positions indexed by {2, 10, 18, 26, 34, 42, 50, 58}, a latest data sample of the fourth 8-tap filter V is inserted into the memory in a circular way among memory positions indexed by {3, 11, 19, 27, 35, 43, 51, 59}, a latest data sample of the fifth 8-tap filter W is inserted into the memory in a circular way among memory positions indexed by {4, 12, 20, 28, 36, 44, 52, 60}, a latest data sample of the sixth 8-tap filter X is inserted into the memory in a circular way among memory positions indexed by {5, 13, 21, 29, 37, 45, 53, 61}, a latest data sample of the seventh 8-tap filter Y is inserted into the memory in a circular way among memory positions indexed by {6, 14, 22, 30, 37, 46, 54, 62}, and a latest data sample of the eighth 8-tap filter Z is inserted into the memory in a circular way among memory positions indexed by {7, 15, 23, 31, 39, 47, 55, 63}.

A head pointer moves in a circular way among the first filter's memory positions indexed by {0, 8, 16, 24, 32, 40, 48, 56}. At time t=7, the head pointer points to the memory position indexed by 0. Hence, as shown in FIG. 6, the filter data of the first 8-tap filter S includes 8 data samples {S7, S6, S5, S4, S3, S2, S1, S0} that are obtained in a time order 7→6→5→4→3→2→1→0 and stored in discontinuous memory positions indexed by {0, 8, 16, 24, 32, 40, 48, 56}, respectively; the filter data of the second 8-tap filter T includes 8 data samples {T7, T6, T5, T4, T3, T2, T1, T0} that are obtained in a time order 7→6→5→4→3→2→1→0 and stored in discontinuous memory positions indexed by {1, 9, 17, 25, 33, 41, 49, 57}, respectively; the filter data of the third 8-tap filter U includes 8 data samples {U7, U6, U5, U4, U3, U2, U1, U0} that are obtained in a time order 7→6→5→4→3→2→1→0 and stored in discontinuous memory positions indexed by {2, 10, 18, 26, 34, 42, 50, 58}, respectively; the filter data of the fourth 8-tap filter V includes 8 data samples {V7, V6, V5, V4, V3, V2, V1, V0} that are obtained in a time order 7→6→5→4→3→2→1→0 and stored in discontinuous memory positions indexed by {3, 11, 19, 27, 35, 43, 51, 59}, respectively; the filter data of the fifth 8-tap filter W includes 8 data samples {W7, W6, W5, W4, W3, W2, W1, W0} that are obtained in a time order 7→6→5→4→3→2→1→0 and stored in discontinuous memory positions indexed by {4, 12, 20, 28, 36, 44, 52, 60}, respectively; the filter data of the sixth 8-tap filter X includes 8 data samples {X7, X6, X5, X4, X3, X2, X1, X0} that re obtained in a time order 7→6→5→4→3→2→1→0 and stored in discontinuous memory positions indexed by {5, 13, 21, 29, 37, 45, 53, 61}, respectively; the filter data of the seventh 8-tap filter Y includes 8 data samples {Y7, Y6, Y5, Y4, Y3, Y2, Y1, Y0} that are obtained in a time order 7→6→5→4→3→2→1→0 and stored in discontinuous memory positions indexed by {6, 14, 22, 30, 37, 46, 54, 62}, respectively; and the filter data of the eighth 8-tap filter Z includes 8 data samples {Z7, Z6, Z5, Z4, Z3, Z2, Z1, Z0} that re obtained in a time order 7→6→5→4→3→2→1→0 and stored in discontinuous memory positions indexed by {7, 15, 23, 31, 39, 47, 55, 63}, respectively.

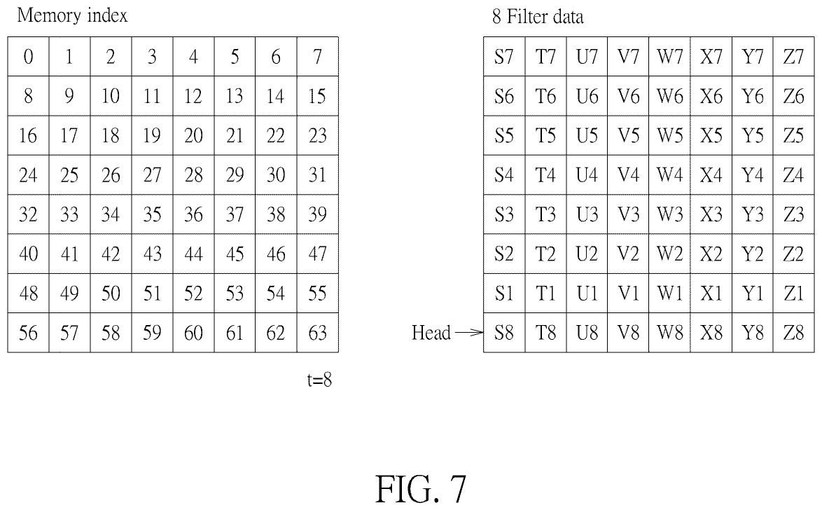

At time t=8, new data samples S8, T8, U8, V8, W8, X8, Y8, Z8 of different filters S, T, U, V, W, X, Y, Z are obtained. As shown in FIG. 7, the head pointer points to the memory position indexed by 56. Regarding the first 8-tap filter S, the earliest data sample S0 stored in the memory position indexed by 56 is updated/overwritten by the new data sample S8. Regarding the second 8-tap filter T, the earliest data sample TO stored in the memory position indexed by 57 is updated/overwritten by the new data sample T8. Regarding the third 8-tap filter U, the earliest data sample U0 stored in the memory position indexed by 58 is updated/overwritten by the new data sample U8. Regarding the fourth 8-tap filter V, the earliest data sample V0 stored in the memory position indexed by 59 is updated/overwritten by the new data sample V8. Regarding the fifth 8-tap filter W, the earliest data sample W0 stored in the memory position indexed by 60 is updated/overwritten by the new data sample W8. Regarding the sixth 8-tap filter X, the earliest data sample X0 stored in the memory position indexed by 61 is updated/overwritten by the new data sample X8. Regarding the seventh 8-tap filter Y, the earliest data sample Y0 stored in the memory position indexed by 62 is updated/overwritten by the new data sample Y8. Regarding the eighth 8-tap filter Z, the earliest data sample Z0 stored in the memory position indexed by 63 is updated/overwritten by the new data sample Z8.

Regarding the first 8-tap filter S, the latest data sample S8 is located at the memory position indexed by 56, and the earliest data sample S1 is located at the memory position indexed by 48. Regarding the second 8-tap filter T, the latest data sample T8 is located at the memory position indexed by 57, and the earliest data sample T1 is located at the memory position indexed by 49. Regarding the third 8-tap filter U, the latest data sample U8 is located at the memory position indexed by 58, and the earliest data sample U1 is located at the memory position indexed by 50. Regarding the fourth 8-tap filter V, the latest data sample V8 is located at the memory position indexed by 59, and the earliest data sample V1 is located at the memory position indexed by 51. Regarding the fifth 8-tap filter W, the latest data sample W8 is located at the memory position indexed by 60, and the earliest data sample W1 is located at the memory position indexed by 52. Regarding the sixth 8-tap filter X, the latest data sample X8 is located at the memory position indexed by 61, and the earliest data sample X1 is located at the memory position indexed by 53. Regarding the seventh 8-tap filter Y, the latest data sample Y8 is located at the memory position indexed by 62, and the earliest data sample Y1 is located at the memory position indexed by 54. Regarding the eight 8-tap filter Z, the latest data sample Z8 is located at the memory position indexed by 63, and the earliest data sample Z1 is located at the memory position indexed by 55. With a proper software-based control of loading data samples from the memory to the filters included in the filter bank, the data samples can be processed by correct taps of the filters included in the filter bank.

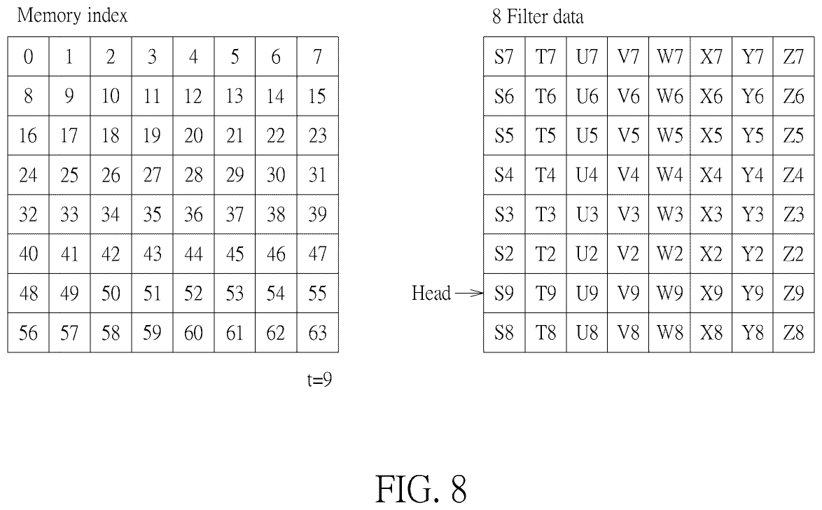

At time t=9, new data samples S9, T9, U9, V9, W9, X9, Y9, Z9 of different filters S, T, U, V, W, X, Y, Z are obtained. As shown in FIG. 8, the head pointer points to the memory position indexed by 48. Regarding the first 8-tap filter S, the earliest data sample S1 stored in the memory position indexed by 48 is updated/overwritten by the new data sample S9. Regarding the second 8-tap filter T, the earliest data sample T1 stored in the memory position indexed by 49 is updated/overwritten by the new data sample T9. Regarding the third 8-tap filter U, the earliest data sample U1 stored in the memory position indexed by 50 is updated/overwritten by the new data sample U9. Regarding the fourth 8-tap filter V, the earliest data sample V1 stored in the memory position indexed by 51 is updated/overwritten by the new data sample V9. Regarding the fifth 8-tap filter W, the earliest data sample W1 stored in the memory position indexed by 52 is updated/overwritten by the new data sample W9. Regarding the sixth 8-tap filter X, the earliest data sample X1 stored in the memory position indexed by 53 is updated/overwritten by the new data sample X9. Regarding the seventh 8-tap filter Y, the earliest data sample Y1 stored in the memory position indexed by 54 is updated/overwritten by the new data sample Y9. Regarding the eighth 8-tap filter Z, the earliest data sample Z1 stored in the memory position indexed by 55 is updated/overwritten by the new data sample Z9.

Regarding the first 8-tap filter S, the latest data sample S9 is located at the memory position indexed by 48, and the earliest data sample S2 is located at the memory position indexed by 40. Regarding the second 8-tap filter T, the latest data sample T9 is located at the memory position indexed by 49, and the earliest data sample T2 is located at the memory position indexed by 41. Regarding the third 8-tap filter U, the latest data sample U9 is located at the memory position indexed by 50, and the earliest data sample U2 is located at the memory position indexed by 42. Regarding the fourth 8-tap filter V, the latest data sample V9 is located at the memory position indexed by 51, and the earliest data sample V2 is located at the memory position indexed by 43. Regarding the fifth 8-tap filter W, the latest data sample W9 is located at the memory position indexed by 52, and the earliest data sample W2 is located at the memory position indexed by 44. Regarding the sixth 8-tap filter X, the latest data sample X9 is located at the memory position indexed by 53, and the earliest data sample X2 is located at the memory position indexed by 45. Regarding the seventh 8-tap filter Y, the latest data sample Y9 is located at the memory position indexed by 54, and the earliest data sample Y2 is located at the memory position indexed by 46. Regarding the eight 8-tap filter Z, the latest data sample Z9 is located at the memory position indexed by 55, and the earliest data sample Z2 is located at the memory position indexed by 47. Similarly, with a proper software-based control of loading data samples from the memory to filters included in the filter bank, the data samples can be processed by correct taps of the filters included in the filter bank.

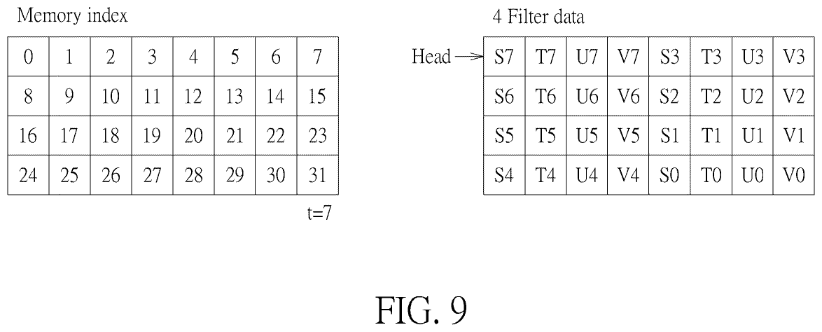

FIGS. 9-11 are diagrams illustrating a circular update scheme applied to a folding-2 group that has data samples loaded and processed by four 8-tap filters in a filter bank according to an embodiment of the present invention. The filter data of a first 8-tap filter S includes 8 data samples that are stored in discontinuous memory positions indexed by {0, 8, 16, 24, 4, 12, 20, 28}, respectively; the filter data of a second 8-tap filter T includes 8 data samples that are stored in stored in discontinuous memory positions indexed by {1, 9, 17, 25, 5, 13, 21, 29}, respectively; the filter data of a third 8-tap filter U includes 8 data samples stored in discontinuous memory positions indexed by {2, 10, 18, 26, 6, 14, 22, 30}, respectively; and the filter data of a fourth 8-tap filter V includes 8 data samples stored in discontinuous memory positions indexed by {3, 11, 19, 27, 7, 15, 23, 31}, respectively.

In accordance with the circular update scheme, a latest data sample of the first 8-tap filter S is inserted into the memory in a circular way among memory positions indexed by {0, 8, 16, 24}, and an earliest data sample of the first 8-tap filter S is overwritten due to data movement performed before insertion of the latest data sample; a latest data sample of the second 8-tap filter T is inserted into the memory in a circular way among memory positions indexed by {1, 9, 17, 25}, and an earliest data sample of the second 8-tap filter T is overwritten due to data movement performed before insertion of the latest data sample; a latest data sample of the third 8-tap filter U is inserted into the memory in a circular way among memory positions indexed by {2, 10, 18, 26}, and an earliest data sample of the third 8-tap filter U is overwritten due to data movement performed before insertion of the latest data sample; and a latest data sample of the fourth 8-tap filter V is inserted into the memory in a circular way among memory positions indexed by {3, 11, 19, 27}, and an earliest data sample of the fourth 8-tap filter V is overwritten due to data movement performed before insertion of the latest data sample.

A head pointer moves in a circular way among the first filter's memory positions indexed by {0, 8, 16, 24}. At time t=7, the head pointer points to the memory position indexed by 0. Hence, as shown in FIG. 9, the filter data of the first 8-tap filter S includes 8 data samples {S7, S6, S5, S4, S3, S2, S1, S0} that are obtained in a time order 7→6→5→4→3→2→1→0 and stored in discontinuous memory positions indexed by {0, 8, 16, 24, 4, 12, 20, 28}, respectively; the filter data of the second 8-tap filter T includes 8 data samples {T7, T6, T5, T4, T3, T2, T1, T0} that are obtained in a time order 7→6→5→4→3→2→1→0 and stored in discontinuous memory positions indexed by {1, 9, 17, 25, 5, 13, 21, 29}, respectively; the filter data of the third 8-tap filter U includes 8 data samples {U7, U6, U5, U4, U3, U2, U1, U0} that are obtained in a time order 7→6→5→4→3→2→1→0 and stored in discontinuous memory positions indexed by {2, 10, 18, 26, 6, 14, 22, 30}, respectively; and the filter data of the fourth 8-tap filter V includes 8 data samples {V7, V6, V5, V4, V3, V2, V1, V0} that are obtained in a time order 7→6→5→4→3→2→1→0 and stored in discontinuous memory positions indexed by {3, 11, 19, 27, 7, 15, 23, 31}, respectively.

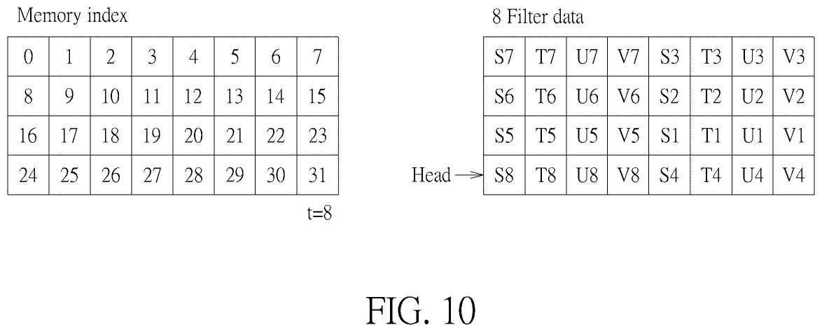

At time t=8, new data samples S8, T8, U8, V8 of different filters S, T, U, V are obtained. As shown in FIG. 10, the head pointer points to the memory position indexed by 24. Regarding the first 8-tap filter S, the earliest data sample S0 stored in the memory position indexed by 28 is updated/overwritten by the data sample S4 due to data movement, and the data sample S4 stored in the memory position indexed by 24 is updated/overwritten by the new data sample S8. Regarding the second 8-tap filter T, the earliest data sample TO stored in the memory position indexed by 29 is updated/overwritten by the data sample T4 due to data movement, and the data sample T4 stored in the memory position indexed by 25 is updated/overwritten by the new data sample T8. Regarding the third 8-tap filter U, the earliest data sample U0 stored in the memory position indexed by 30 is updated by the data sample U4 due to data movement, and the data sample U4 stored in the memory position indexed by 26 is updated/overwritten by the new data sample U8. Regarding the fourth 8-tap filter V, the earliest data sample V0 stored in the memory position indexed by 31 is updated/overwritten by the data sample V4 due to data movement, and the data sample V4 stored in the memory position indexed by 27 is updated/overwritten by the new data sample V8.

Regarding the first 8-tap filter S, the data samples {S8, S7, S6, S5, S4, S3, S2, S1} are located at the memory positions indexed by {24, 0, 8, 16, 28, 4, 12, 20}, respectively. Regarding the second 8-tap filter T, the data samples {T8, T7, T6, T5, T4, T3, T2, T1} are located at the memory positions indexed by {25, 1, 9, 17, 29, 5, 13, 21}, respectively. Regarding the third 8-tap filter U, the data samples {U8, U7, U6, U5, U4, U3, U2, U1} are located at the memory positions indexed by {26, 2, 10, 18, 30, 6, 14, 22}, respectively. Regarding the fourth 8-tap filter V, the data samples {V8, V7, V6, V5, V4, V3, V2, V1} are located at the memory positions indexed by {27, 3, 11, 19, 31, 7, 15, 23}, respectively. With a proper software-based control of loading data samples from the memory to the filters included in the filter bank, the data samples can be processed by correct taps of the filters included in the filter bank.

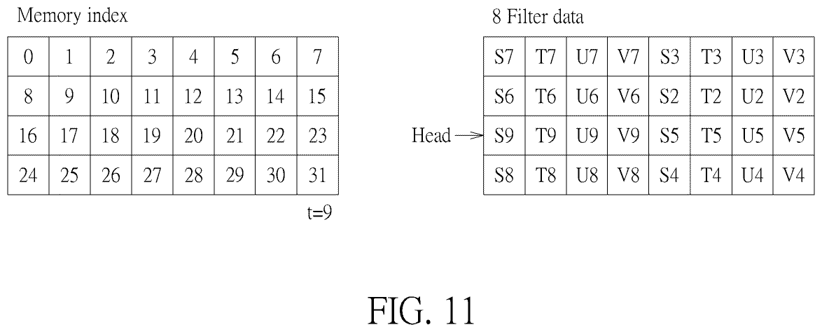

At time t=9, new data samples S9, T9, U9, V9 of different filters S, T, U, V are obtained. As shown in FIG. 11, the head pointer points to the memory position indexed by 16. Regarding the first 8-tap filter S, the earliest data sample S1 stored in the memory position indexed by 20 is updated/overwritten by the data sample S5 due to data movement, and the data sample S5 stored in the memory position indexed by 16 is updated/overwritten by the new data sample S9. Regarding the second 8-tap filter T, the earliest data sample T1 stored in the memory position indexed by 21 is updated/overwritten by the data sample T5 due to data movement, and the data sample T5 stored in the memory position indexed by 17 is updated/overwritten by the new data sample T9. Regarding the third 8-tap filter U, the earliest data sample U1 stored in the memory position indexed by 22 is updated/overwritten by the data sample U5 due to data movement, and the data sample U5 stored in the memory position indexed by 18 is updated/overwritten by the new data sample U9. Regarding the fourth 8-tap filter V, the earliest data sample V1 stored in the memory position indexed by 23 is updated/overwritten by the data sample V5 due to data movement, and the data sample V5 stored in the memory position indexed by 19 is updated/overwritten by the new data sample V9.

Regarding the first 8-tap filter S, the data samples {S9, S8, S7, S6, S5, S4, S3, S2} are located at the memory positions indexed by {16, 24, 0, 8, 20, 28, 4, 12}, respectively. Regarding the second 8-tap filter T, the data samples {T9, T8, T7, T6, T5, T4, T3, T2} are located at the memory positions indexed by {17, 25, 1, 9, 21, 29, 5, 13}, respectively. Regarding the third 8-tap filter U, the data samples {U9, U8, U7, U6, U5, U4, U3, U2} are located at the memory positions indexed by {18, 26, 2, 10, 22, 30, 6, 14}, respectively. Regarding the fourth 8-tap filter V, the data samples {V9, V8, V7, V6, V5, V4, V3, V2} are located at the memory positions indexed by {19, 27, 3, 11, 23, 31, 7, 15}, respectively. With a proper software-based control of loading data samples from the memory to the filters included in the filter bank, the data samples can be processed by correct taps of the filters included in the filter bank.

Briefly summarized, once one can locate the latest data of a filter, the filtering can be carried out by following the data order. When new data of streaming is coming, head is updated in a circular way at the first filter of the first group. Consider a case where the filter length is L and the first group (which is a non-folding group) has N filters. The circular update of head can be expressed by {N·L, N·(L−1), N·(L−2), . . . , 0}, and the latest data location of each filter can be expressed by {P, P+1, P+2, . . . , P+N−1}, where P=(L−T % L)·N for time T. Consider another case where the filter length is L and the first group (which is an M-folding group) has N filters. The circular update of head can be expressed by {N·K, N·(K−1), N·(K−2), . . . , 0}, where K=L/M; and the latest data location of each filter can be expressed by {P, P+1, P+2, . . . , P+N−1}, where P=(K−T % K)·N for time T.

It should be noted that the present invention has no limitations on a load method adopted for loading data samples from the memory into filters of the filter bank. Furthermore, if the filter length is not dividable by the folding size, dummy data samples may be added; and if fast hardware instructions require the alignment, the folding size that can lead to correct alignment may be chosen. To put it simply, any filter bank computation using the proposed data arrangement design falls within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A digital signal processing system comprising:
a memory, arranged to store a plurality of data samples; and
a filter bank, arranged to process the plurality of data samples stored in the memory, and comprising:
a plurality of filters, wherein the plurality of filters comprise a first group of filters that is arranged to process a first group of data samples included in the plurality of data samples stored in the memory, the first group of data samples comprises data samples loaded and processed by taps of each filter included in the first group of filters that are stored in discontinuous memory positions of the memory.

2. The digital signal processing system of claim 1, wherein the first group of data samples comprises data samples loaded and processed by different filters included in the first group of filters that are stored in continuous memory positions of the memory.

3. The digital signal processing system of claim 2, wherein the first group of filters comprises a first filter and a second filter; the first group of data samples comprises a plurality of first data samples loaded and processed by the first filter and a plurality of second data samples loaded and processed by the second filter; one first data sample of the plurality of first data samples and one second data sample of the plurality of second data samples are stored in continuous memory positions of the memory; another first data sample of the plurality of first data samples and another second data sample of the plurality of second data samples are stored in continuous memory positions of the memory; and the another first data sample is processed by a second tap of the first filter and the another second data sample is processed by a second tap of the second filter after the one first data sample is processed by a first tap of the first filter and the one second data sample is processed by a first tap of the second filter.

4. The digital signal processing system of claim 1, further comprising:
a plurality of accumulation (ACC) registers;
wherein a number of filters included in the first group of filters is equal to a number of the plurality of ACC registers; the first group of data samples includes data samples loaded and processed by taps of different filters included in the first group of filters that are stored in continuous memory positions of the memory, where the taps of the different filters included in the first group of filters comprise a single tap of each filter included in the first group of filters.

5. The digital signal processing system of claim 4, wherein the plurality of filters further comprise a second group of filters that is arranged to process a second group of data samples included in the plurality of data samples stored in the memory after the first group of filters finishes processing of the first group of data samples; a number of filters included in the second group of filters is equal to the number of the plurality of ACC registers; the second group of data samples includes data samples loaded and processed by taps of each filter included in the second group of filters that are stored in discontinuous memory positions of the memory, and includes data samples loaded and processed by taps of different filters included in the second group of filters that are stored in continuous memory positions of the memory, where the taps of the different filters included in the second group of filters comprise a single tap of each filter included in the second group of filters.

6. The digital signal processing system of claim 4, wherein the plurality of filters further comprise a second group of filters that is arranged to process a second group of data samples included in the plurality of data samples stored in the memory; a number of filters included in the second group of filters is smaller than the number of the plurality of ACC registers; the second group of data samples includes data samples loaded and processed by taps of each filter included in the second group of filters that are stored in discontinuous memory positions of the memory, and includes data samples loaded and processed by taps of different filters included in the second group of filters that are stored in continuous memory positions of the memory, where the taps of the different filters included in the second group of filters comprise multiple taps of each filter included in the second group of filters.

7. The digital signal processing system of claim 6, wherein the number of the plurality of ACC registers is divisible by the number of filters included in the second group of filters.

8. The digital signal processing system of claim 6, wherein the plurality of filters further comprise a third group of filters that is arranged to process a third group of data samples included in the plurality of data samples stored in the memory; a number of filters included in the third group of filters is smaller than the number of the plurality of ACC registers, and is different from the number of filters included in the second group of filters; the third group of data samples includes data samples loaded and processed by taps of each filter included in the third group of filters that are stored in discontinuous memory positions of the memory, and includes data samples loaded and processed by taps of different filters included in the third group of filters that are stored in continuous memory positions of the memory, where the taps of the different filters included in the third group of filters comprise multiple taps of each filter included in the third group of filters.

9. The digital signal processing system of claim 8, wherein the number of the plurality of ACC registers is divisible by the number of filters included in the second group of filters, and is also divisible by the number of filters included in the third group of filters.

10. The digital signal processing system of claim 8, wherein the number of filters included in the second group of filters is larger than the number of filters included in the third group of filters; and the third group of filters is arranged to process the third group of data samples after the second group of filters finishes processing of the second group of data samples.

11. The digital signal processing system of claim 4, wherein the second group of filters is arranged to process the second group of data samples after the first group of filters finishes processing of the first group of data samples.

12. The digital signal processing system of claim 1, further comprising:
a plurality of accumulation (ACC) registers;
wherein a number of filters included in the first group of filters is smaller than a number of the plurality of ACC registers; the first group of data samples includes data samples loaded and processed by taps of each filter included in the first group of filters that are stored in discontinuous memory positions of the memory, and includes data samples loaded and processed by taps of different filters included in the first group of filters that are stored in continuous memory positions of the memory, where the taps of the different filters included in the first group of filters comprise multiple taps of each filter included in the first group of filters.

13. The digital signal processing system of claim 12, wherein the number of the plurality of ACC registers is divisible by the number of filters included in the first group of filters.

14. The digital signal processing system of claim 12, wherein the plurality of filters further comprise a second group of filters that is arranged to process a second group of data samples included in the plurality of data samples stored in the memory; a number of filters included in the second group of filters is smaller than the number of the plurality of ACC registers, and is different from the number of filters included in the first group of filters; the second group of data samples includes data samples loaded and processed by taps of each filter included in the second group of filters that are stored in discontinuous memory positions of the memory, and includes data samples loaded and processed by taps of different filters included in the second group of filters that are stored in continuous memory positions of the memory, where the taps of the different filters included in the second group of filters comprise multiple taps of each filter included in the second group of filters.

15. The digital signal processing system of claim 14, wherein the number of the plurality of ACC registers is divisible by the number of filters included in the first group of filters, and is also divisible by the number of filters included in the second group of filters.

16. The digital signal processing system of claim 14, wherein the number of filters included in the first group of filters is larger than the number of filters included in the second group of filters; and the second group of filters is arranged to process the second group of data samples after the first group of filters finishes processing of the first group of data samples.

17. The digital signal processing system of claim 1, wherein when a latest data sample to be processed by said each filter included in the first group of filters comes, the latest data sample is inserted into the memory in a circular way among a plurality of selected memory positions, and an earliest data sample that is stored in the memory and processed by said each filter is overwritten by the latest data sample or a data sample shifted from a selected memory position before the latest data sample is stored into the selected memory position.

18. The digital signal processing system of claim 1, wherein each of the plurality of data samples is an audio sample.

19. A data arrangement method applied to a memory accessible to a filter bank, comprising:
storing filter data of the filter bank into the memory, wherein the filter data comprises a plurality of data samples, the plurality of data samples comprise a first group of data samples for a first group of filters included in the filter bank, the first group of data samples comprises data samples loaded and processed by taps of each filter included in the first group of filters that are stored in discontinuous memory positions of the memory.

20. The data arrangement method of claim 19, wherein each of the plurality of data samples is an audio sample.
